(19) United States
(12) Patent Application Publication
(10) Pub. No.: US 2025/0344490 A1
(43) Pub. Date: Nov. 6, 2025

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventor: Hiroyuki IRIFUNE, Ibo Hyogo (JP)

(21) Appl. No.: 19/268,318

(22) Filed: Jul. 14, 2025

Related U.S. Application Data
(63) Continuation of application No. PCT/JP2024/004145, filed on Feb. 7, 2024.

(30) Foreign Application Priority Data
Sep. 19, 2023 (JP) 2023-151620

(51) Int. Cl. H10D 84/00; H10D 62/832

(52) U.S. Cl. CPC H10D 84/146; H10D 62/8325

(57) ABSTRACT

According to one embodiment, a semiconductor device includes a first electrode, a second electrode, a third electrode, a first semiconductor member of a first conductivity type, a second semiconductor member of a second conductivity type, a third semiconductor member of the first conductivity type, a fourth semiconductor member, and a first insulating member. The first semiconductor member includes first to third partial regions. The second semiconductor member includes first and second regions. The third semiconductor member is electrically connected to the second electrode. The fourth semiconductor member is electrically connected to the second electrode. The fourth semiconductor member is of the first conductivity type, or does not include an impurity of the second conductivity type.

The first insulating member includes a first insulating region provided between the third partial region and at least a portion of the third electrode.

### CROSS-REFERENCE TO RELATED APPLICATIONS

This is a continuation application of International Application PCT/JP2024/004145, filed on Feb. 7, 2024. This application also claims priority to Japanese Patent Application No. 2023-151620, filed on Sep. 19, 2023. The entire contents of which are incorporated herein by reference.

### FIELD

Embodiments described herein generally relate to a semiconductor device.

### BACKGROUND

For example, it is desired to improve the characteristics of semiconductor devices.

### BRIEF DESCRIPTION OF THE DRAWINGS

FIG. 1 is a schematic cross-sectional view illustrating a semiconductor device according to a first embodiment;

FIG. 2 is a schematic plan view illustrating a part of the semiconductor device according to the first embodiment;

FIG. 3 is a schematic plan view illustrating a part of the semiconductor device according to the first embodiment;

FIG. 4 is a schematic plan view illustrating a part of the semiconductor device according to the first embodiment;

FIG. 5 is a schematic cross-sectional view illustrating a semiconductor device according to a second embodiment; and

FIG. 6 is a schematic cross-sectional view illustrating a semiconductor device according to a third embodiment.

### DETAILED DESCRIPTION

According to one embodiment, a semiconductor device includes a first electrode, a second electrode, a third electrode, a first semiconductor member of a first conductivity type, a second semiconductor member of a second conductivity type, a third semiconductor member of the first conductivity type, a fourth semiconductor member, and a first insulating member. The first semiconductor member is provided between the first electrode and the second electrode, and includes a first partial region, a second partial region, and a third partial region. A second direction from the first partial region to the second partial region crosses a first direction from the first electrode to the second electrode. A direction from the first partial region to the third partial region is along the first direction. The second semiconductor member includes a first semiconductor region and a second semiconductor region. The first semiconductor region is provided between the third partial region and the third semiconductor member in the second direction. The third semiconductor member is electrically connected to the second electrode. The second semiconductor region is provided between the second partial region and the fourth semiconductor member in the first direction. The fourth semiconductor member is electrically connected to the second electrode. The fourth semiconductor member is of the first conductivity type, or does not include an impurity of the second conductivity type. The third partial region is provided between the first partial region and the third electrode in the first direction. The first insulating member includes a first insulating region. The first insulating region is provided between the third partial region and at least a portion of the third electrode.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously in an antecedent drawing are marked with like reference numerals, and a detailed description is omitted as appropriate.

### First Embodiment

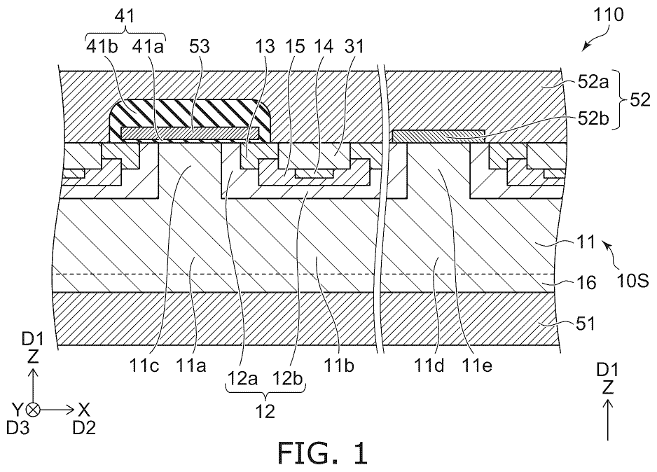

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a first semiconductor member 11, a second semiconductor member 12, a third semiconductor member 13, a fourth semiconductor member 14, and a first insulating member 41. The first semiconductor member 11, the second semiconductor member 12, the third semiconductor member 13, and the fourth semiconductor member 14 may be included in a semiconductor layer 11S.

A first direction D1 from the first electrode 51 to the second electrode 52 is defined as a Z-axis direction. A direction perpendicular to the Z-axis direction is defined as an X-axis direction. A direction perpendicular to the Z-axis direction and the X-axis direction is defined as a Y-axis direction.

The first semiconductor member 11 is provided between the first electrode 51 and the second electrode 52. The first semiconductor member 11 is of a first conductivity type. The first semiconductor member 11 includes a first partial region 11a, a second partial region 11b, and a third partial region 11c. A second direction D2 from the first partial region 11a toward the second partial region 11b crosses the first direction D1 from the first electrode 51 toward the second electrode 52. The second direction D2 may be, for example, the X-axis direction.

A direction from the first partial region 11a to the third partial region 11c is along the first direction D1.

The second semiconductor member 12 is of a second conductivity type. The first conductivity type is one of n-type and p-type. The second conductivity type is the other of the n-type and the p-type. Hereinafter, it is assumed that the first conductivity type is n-type and the second conductivity type is p-type.

The second semiconductor member 12 includes a first semiconductor region 12a and a second semiconductor region 12b.

The third semiconductor member 13 is of the first conductivity type. The first semiconductor region 12a is provided between the third partial region 11c and the third semiconductor member 13 in the second direction D2. The third semiconductor member 13 is electrically connected to the second electrode 52.

The second semiconductor region 12b is provided between the second partial region 11b and the fourth semiconductor member 14 in the first direction D1. The fourth semiconductor member 14 is electrically connected to the second electrode 52. The fourth semiconductor member 14 satisfies a first condition or a second condition. In the first condition, the fourth semiconductor member 14 is of the first conductivity type. In the second condition, the fourth semiconductor member 14 does not substantially include an impurity of the second conductivity type. In the second condition, the fourth semiconductor member 14 may be, for example, an intrinsic layer (i-layer).

The third partial region 11c is provided between the first partial region 11a and the third electrode 53 in the first direction D1.

The first insulating member 41 includes a first insulating region 41a. The first insulating region 41a is provided between the third partial region 11c and at least a portion of the third electrode 53.

In the semiconductor device 110, a current between the first electrode 51 and the second electrode 52 can be controlled by a potential of the third electrode 53. The potential of the third electrode 53 may be a potential based on a potential of the second electrode 52. The first electrode 51 functions as, for example, a drain electrode. The second electrode 52 functions as, for example, a source electrode. The third electrode 53 functions as, for example, a gate electrode. The semiconductor device 110 is, for example, a transistor (for example, a MOS transistor). The first insulating region 41a is, for example, a gate insulating film.

In the embodiment, for example, the fourth semiconductor member 14 described above is provided. The resistance can be increased in a current path including the fourth semiconductor member 14. For example, transient characteristics at the time of switching can be made gentle. For example, a voltage change (dV/dt) with respect to a time change can be reduced. Thereby, for example, switching noise can be reduced. According to the embodiment, it is possible to provide a semiconductor device capable of improving characteristics.

In one example of the case where the fourth semiconductor member 14 is of the first conductivity type, a fourth impurity concentration of the first conductivity type in the fourth semiconductor member 14 may be higher than a first impurity concentration of the first conductivity type in the first semiconductor member 11. Switching noise can be further reduced.

In the semiconductor device 110, a third impurity concentration of the first conductivity type in the third semiconductor member 13 is higher than the first impurity concentration of the first conductivity type in the first semiconductor member 11. The third semiconductor member 13 is in contact with, for example, the second electrode 52. The first semiconductor member 11 is, for example, an n-layer. The third semiconductor member 13 is, for example, an n⁺-layer. The first semiconductor member 11 is, for example, an n-drift layer.

As shown in FIG. 1, the semiconductor device 110 may further include a fifth semiconductor member 15. The fifth semiconductor member 15 is of the second conductivity type. At least a portion of the fifth semiconductor member 15 is provided between the second partial region 11b and the second electrode 52 in the first direction D1. A fifth impurity concentration of the 35 second conductivity type in the fifth semiconductor member 15 is higher than a second impurity concentration of the second conductivity type in the second semiconductor member 12. The second semiconductor member 12 is, for example, a p-layer. The fifth semiconductor member 15 is, for example, a p⁺-layer.

As shown in FIG. 1, a portion of the first semiconductor region 12a may be provided between the third partial region 11c and the fifth semiconductor member 15 in the second direction D2. A portion of the fifth semiconductor member 15 may be provided between the first semiconductor region 12a and the fourth semiconductor member 14 in the second direction D2. A portion of the fifth semiconductor member 15 may be provided between a portion of the fourth semiconductor member 14 and another portion of the fourth semiconductor member 14 in the second direction D2.

As shown in FIG. 1, the semiconductor device 110 may further include a first conductive layer 31. The first conductive layer 31 includes silicide. The first conductive layer 31 includes, for example, Ni and Si. The first conductive layer 31 is provided between the fourth semiconductor member 14 and the second electrode 52 and between the third semiconductor member 13 and the second electrode 52. By providing the first conductive layer 31, a good ohmic contact is easily obtained. For example, the first conductive layer 31 is in contact with the second electrode 52.

In the example, at least a portion of the first conductive layer 31 is provided between a portion of the fifth semiconductor member 15 and another portion of the fifth semiconductor member 15 in the second direction D2.

As shown in FIG. 1, in the semiconductor device 110, the first semiconductor member 11 may further include a fourth partial region 11d and a fifth partial region 11e. A direction from the first partial region 11a toward the fourth partial region 11d crosses the first direction D1. For example, the direction from the first partial region 11a toward the fourth partial region 11d may be along the second direction D2. The direction from the first partial region 11a to the fourth partial region 11d may be any direction crossing the first direction D1. The direction from the fourth partial region 11d to the fifth partial region 11e is along the first direction D1.

The fifth partial region 11e is in Schottky contact with the second electrode 52. A portion including the fifth partial region 11e and the second electrode 52 functions as, for example, a Schottky barrier diode (SBD). By providing the SBD, for example, the withstand capability of the semiconductor device 110 when a “reverse voltage” is applied can be improved. When the “reverse voltage” is applied, the potential of the second electrode 52 is higher than the potential of the first electrode 51.

As shown in FIG. 1, the second electrode 52 may include a first electrode portion 52a and a second electrode portion 52b. The second electrode portion 52b is provided between the fifth partial region 11e and the first electrode portion 52a. The second electrode portion 52b includes, for example, at least one selected from the group consisting of Ni, Ti, V, and Mo. By providing the second electrode portion 52b, a Schottky barrier can be stably obtained.

For example, the SBD and the fourth semiconductor member 14 are combined. Thereby, for example, when a reverse voltage is applied, the hole injection start current can be increased in the static characteristic mode. On the other hand, in the I-surge mode, the break down easily occurs in the diode formed between the fourth semiconductor member 14 and the second semiconductor member 12. Thereby, it becomes easy to increase the flowing current. For example, a large IFSM (peak one-cycle surge current) is easily obtained. Stable characteristics can be easily obtained. According to the embodiment, it is possible to provide a semiconductor device capable of improving characteristics.

As shown in FIG. 1, the semiconductor device 110 may further include a sixth semiconductor member 16 of the first conductivity type. The sixth semiconductor member 16 is provided between the first electrode 51 and the first semiconductor member 11. A sixth impurity concentration of the first conductivity type in the sixth semiconductor member 16 is higher than the first impurity concentration of the first conductivity type in the first semiconductor member 11. The sixth semiconductor member 16 is, for example, an n⁺-layer.

As shown in FIG. 1, the first insulating member 41 may further include a second insulating region 41b. At least a portion of the second insulating region 41b is provided between the third electrode 53 and the second electrode 52.

FIG. 2 is a schematic plan view illustrating a part of the semiconductor device according to the first embodiment.

FIG. 2 is a schematic plan view of a portion including the fourth semiconductor member 14 in the semiconductor device 110. As shown in FIG. 2, in the semiconductor device 110, the third electrode 53 extends along a third direction D3. The third direction D3 crosses a plane including the first direction D1 and the second direction D2. The third direction D3 may be, for example, the Y-axis direction. In the example, the fourth semiconductor member 14 extends along the third direction D3.

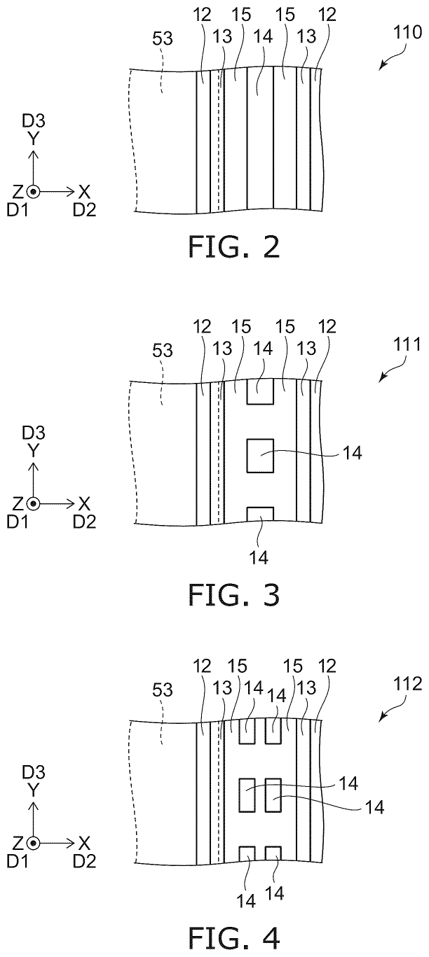

FIG. 3 is a schematic plan view illustrating a part of the semiconductor device according to the first embodiment.

FIG. 3 illustrates a part of a semiconductor device 111 according to the embodiment. The configuration of the fourth semiconductor member 14 in the semiconductor device 111 is different from the configuration of the fourth semiconductor member 14 in the semiconductor device 110. The configuration of the semiconductor device 111 except for this may be the same as the configuration of the semiconductor device 110.

As shown in FIG. 3, also in the semiconductor device 111, the third electrode 53 extends along the third direction D3. As described above, the third direction D3 crosses the plane including the first direction D1 and the second direction D2. In the semiconductor device 111, a plurality of fourth semiconductor members 14 are provided. A direction from one of the plurality of fourth semiconductor members 14 to another one of the plurality of fourth semiconductor members 14 is along the third direction D3. A portion of the fifth semiconductor member 15 may be provided between one of the plurality of fourth semiconductor members 14 and another one of the plurality of fourth semiconductor members 14.

FIG. 4 is a schematic plan view illustrating a part of the semiconductor device according to the first embodiment.

FIG. 4 illustrates a part of a semiconductor device 112 according to the embodiment. The configuration of the fourth semiconductor member 14 in the semiconductor device 112 is different from the configuration of the fourth semiconductor member 14 in the semiconductor device 110. The configuration of the semiconductor device 112 except for this may be the same as the configuration of the semiconductor device 110.

As shown in FIG. 4, also in the semiconductor device 112, the third electrode 53 extends along the third direction D3. The third direction D3 crosses a plane including the first direction D1 and the second direction D2. A plurality of fourth semiconductor members 14 are provided. A direction from one of the plurality of fourth semiconductor members 14 toward another one of the plurality of fourth semiconductor members 14 is along the second direction D2. A portion of the fifth semiconductor member 15 may be provided between one of the plurality of fourth semiconductor members 14 and another one of the plurality of fourth semiconductor members 14.

As shown in FIG. 4, in the semiconductor device 112, the plurality of fourth semiconductor members 14 may be arranged along the second direction D2 and the third direction D3. A portion of the fifth semiconductor member 15 is provided between the plurality of fourth semiconductor members 14.

In the semiconductor devices 110 to 112, the characteristics can be controlled by the arrangement, the area ratio, and the like of the fourth semiconductor member 14.

In one example according to the first embodiment, the concentration of the impurity of the first conductivity type in the first semiconductor member 11 is, for example, not less than 1×10¹⁴ cm⁻³ and not more than 1×10¹⁷ cm⁻³. In one example according to the first embodiment, the concentration of the impurity of the second conductivity type in the second semiconductor member 12 is, for example, not less than 1×10¹⁶ cm⁻³ and not more than 1×10²⁰ cm⁻³. In one example according to the first embodiment, the concentration of the impurity of the second conductivity type in the third semiconductor member 13 is, for example, not less than 1×10¹⁹ cm⁻³ and not more than 1×10²¹ cm⁻³.

In one example of the first condition, the concentration of the impurity of the first conductivity type in the fourth semiconductor member 14 is, for example, not less than 1×10¹⁶ cm⁻³ and not more than 1×10²¹ cm⁻³. In one example of the second condition, the concentration of the impurity of the second conductivity type in the fourth semiconductor member 14 is not more than 1×10¹⁵ cm⁻³.

In one example according to the first embodiment, the concentration of the impurity of the second conductivity type in the fifth semiconductor member 15 is, for example, not less than 1×10¹⁶ cm⁻³ and not more than 1×10²¹ cm⁻³. In one example according to the first embodiment, the concentration of the impurity of the first conductivity type in the sixth semiconductor member 16 is, for example, not less than 1×10¹⁵ cm⁻³ and not more than 1×10¹⁹ cm⁻³. The impurity concentration may be substantially a carrier concentration, for example.

### Second Embodiment

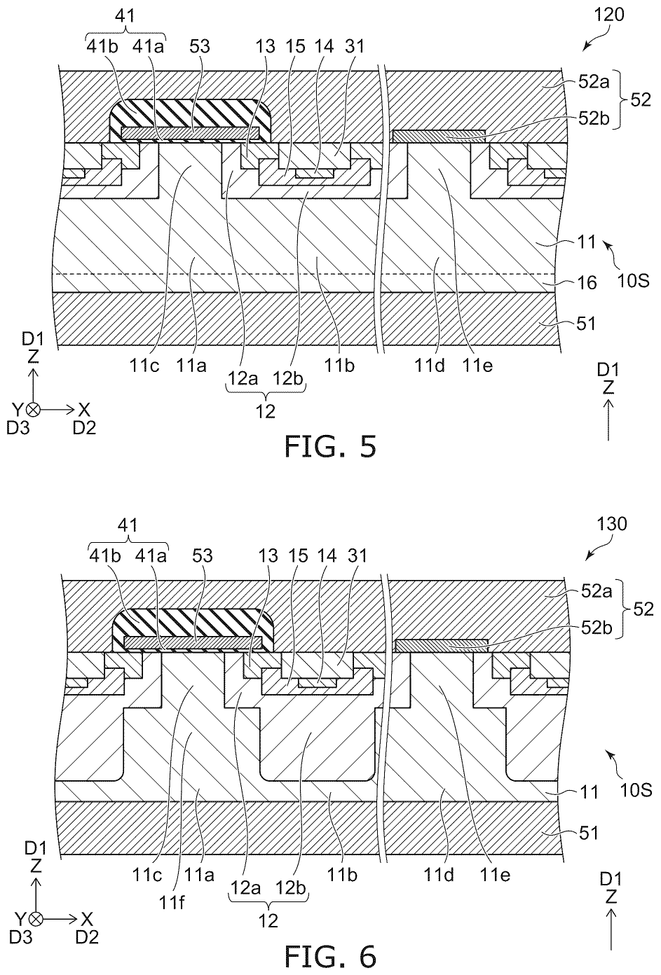

FIG. 5 is a schematic cross-sectional view illustrating a semiconductor device according to a second embodiment.

As shown in FIG. 5, a semiconductor device 120 according to the embodiment includes the first electrode 51, the second electrode 52, the third electrode 53, the first semiconductor member 11, the second semiconductor member 12, the third semiconductor member 13, the fourth semiconductor member 14, the fifth semiconductor member 15, and the first insulating member 41. In the semiconductor device 120, the fourth semiconductor member 14 is of the second conductivity type. The configuration of the semiconductor device 120 except for this may be the same as the configurations of the semiconductor devices 110 to 112.

In the semiconductor device the fourth 120, semiconductor member 14 is of the second conductivity type. The second semiconductor region 12b is provided between the second partial region 11b and the fourth semiconductor member 14 in the first direction D1. The fourth semiconductor member 14 is electrically connected to the second electrode 52.

The fifth semiconductor member 15 is of the second conductivity type. At least a portion of the fifth semiconductor member 15 is provided between the second partial region 11b and the second electrode 52 in the first direction D1. The fifth impurity concentration of the second conductivity type in the fifth semiconductor member 15 is higher than the second impurity concentration of the second conductivity type in the second semiconductor member 12. The fifth impurity concentration is higher than the fourth impurity concentration of the second conductivity type of the fourth semiconductor member 14.

The third partial region 11c is provided between the first partial region 11a and the third electrode 53 in the first direction D1. The first insulating region 41a of the first insulating member 41 is provided between the third partial region 11c and at least a portion of the third electrode 53.

In the semiconductor device 120, the resistance can be increased in the current path including the fourth semiconductor member 14. For example, transient characteristics at the time of switching can be made gentle. For example, the voltage change (dV/dt) with respect to a time change can be reduced. Thereby, for example, switching noise can be reduced. According to the embodiment, it is possible to provide a semiconductor device capable of improving characteristics.

In the semiconductor device 120, the first semiconductor member 11 may further include the fourth partial region 11d and the fifth partial region 11e. The fifth partial region 11e is in Schottky contact with the second electrode 52. A portion including the fifth partial region 11e and the second electrode 52 functions as, for example, a Schottky barrier diode (SBD). By providing the SBD, for example, the withstand capability when a reverse voltage is applied can be improved. For example, the SBD and the fourth semiconductor member 14 are combined. Thereby, for example, when a reverse voltage is applied, the hole injection start current can be increased in the static characteristic mode. On the other hand, in the I-surge mode, the break down easily occurs in the diode formed between the fourth semiconductor member 14 and the second semiconductor member 12. Thereby, it becomes easy to increase the flowing current. For example, a large IFSM (peak one-cycle surge current) is easily obtained. Stable characteristics can be easily obtained. According to the embodiment, it is possible to provide a semiconductor device capable of improving characteristics.

In one example according to the second embodiment, the concentration of the impurity of the second conductivity type in the fourth semiconductor member 14 is, for example, not less than 1×10¹⁶ cm⁻³ and not more than 1×10²¹ cm⁻³. In the semiconductor device 120, the configurations described with respect to the semiconductor devices 110 to 112 may be applied within a technically possible range.

### Third Embodiment

FIG. 6 is a schematic cross-sectional view illustrating a semiconductor device according to a third embodiment.

As shown in FIG. 6, a semiconductor device 130 according to the embodiment includes the first electrode 51, the second electrode 52, the third electrode 53, the first semiconductor member 11, the second semiconductor member 12, the third semiconductor member 13, the fourth semiconductor member 14, the fifth semiconductor member 15, and the first insulating member 41. In the semiconductor device 130, the fourth semiconductor member 14 may have the configuration described in relation to the first embodiment or the second embodiment. In the semiconductor device 130, the first semiconductor member 11 includes the sixth partial region 11f. The sixth partial region 11f is provided between the first partial region 11a and the third partial region 11c in the first direction D1. The direction from the third partial region 11c toward the second semiconductor region 12b is along the second direction D2. The configuration of the semiconductor device 130 except for this may be the same as the configuration of the semiconductor devices 110 to 112 or the semiconductor device 120.

In the semiconductor device 130, the sixth partial region 11f is, for example, an n-pillar (or an n-drift layer). The second semiconductor region 12b is, for example, a p-type pillar. A plurality of structures including the sixth partial region 11f and the second semiconductor region 12b may be provided. For example, the total amount of carriers in the n-drift layer is substantially the same as the total amount of carriers in the p-type pillar. The semiconductor device 130 has, for example, a super junction structure. For example, even when the impurity concentration in the n-drift layer is increased to reduce the on-resistance, a high breakdown voltage can be maintained.

In the semiconductor device 130, the capacitance is likely to change steeply. In the semiconductor device 130, the change in the total gate charge amount (Qg) is large. In such a configuration, switching noise is likely to increase in the case of a multi-chip configuration. In the semiconductor device 130, a voltage change (dV/dt) with respect to a temporal change can be mitigated by the fourth semiconductor member 14. Thus, switching noise can be reduced.

In the first embodiment, the second embodiment, and the third embodiment, for example, the gate electrode (third electrode 53) may be provided in the trench provided in the n-drift layer (first semiconductor member 11) via the gate insulating film (first insulating region 41a). For example, the embodiments may be applied to a so-called trench gate electrode structure.

In the first embodiment, the second embodiment, and the third embodiment, for example, the first semiconductor member 11, the second semiconductor member 12, the third semiconductor member 13, and the fourth semiconductor member 14 include SiC. The first semiconductor member 11, the second semiconductor member 12, the third semiconductor member 13, and the fourth semiconductor member 14 may include at least one selected from the group consisting of 4H—SiC, 6H—SiC, and 3C—SiC. These semiconductor members include crystals. These semiconductor members may include silicon. These semiconductor members may include a compound semiconductor including Ga.

For example, the impurity of the first conductivity type includes at least one selected from the group consisting of N, P, and As. For example, the impurity of the second conductivity type includes at least one selected from the group consisting of B, Al, and Ga.

In the embodiment, information on the length and the thickness is obtained by electron microscope observation or the like. The information on the composition of the material is obtained by SIMS (Secondary Ion Mass Spectrometry), EDX (Energy dispersive X-ray spectroscopy), or the like.

The embodiments may include the following Technical proposals:

### (Technical Proposal 1)

A semiconductor device, comprising:
a first electrode;
a second electrode;
a first semiconductor member of a first conductivity type, the first semiconductor member being provided between the first electrode and the second electrode, the first semiconductor member including a first partial region, a second partial region, and a third partial region, a second direction from the first partial region to the second partial region crossing a first direction from the first electrode to the second electrode, a direction from the first partial region to the third partial region being along the first direction;
a second semiconductor member of a second conductivity type, the second semiconductor member including a first semiconductor region and a second semiconductor region;
a third semiconductor member of the first conductivity type, the first semiconductor region being provided between the third partial region and the third semiconductor member in the second direction, the third semiconductor member being electrically connected to the second electrode;
a fourth semiconductor member, the second semiconductor region being provided between the second partial region and the fourth semiconductor member in the first direction, the fourth semiconductor member being electrically connected to the second electrode, the fourth semiconductor member being of the first conductivity type, or the fourth semiconductor member not including an impurity of the second conductivity type;
a third electrode, the third partial region being provided between the first partial region and the third electrode in the first direction; and
a first insulating member including a first insulating region, the first insulating region being provided between the third partial region and at least a portion of the third electrode.

### (Technical Proposal 2)

The semiconductor device according to Technical proposal 1, wherein
a fourth impurity concentration of the first conductivity type in the fourth semiconductor member is higher than a first impurity concentration of the first conductivity type in the first semiconductor member.

### (Technical Proposal 3)

The semiconductor device according to Technical proposal 1 or 2, further comprising:
a fifth semiconductor member of the second conductivity type,
at least a portion of the fifth semiconductor member being provided between the second partial region and the second electrode in the first direction,

### (Technical Proposal 4)

A semiconductor device, comprising:
a first electrode;
a second electrode;
a first semiconductor member of a first conductivity type, the first semiconductor member being provided between the first electrode and the second electrode, the first semiconductor member including a first partial region, a second partial region, and a third partial region, a second direction from the first partial region to the second partial region crossing a first direction from the first electrode to the second electrode, a direction from the first partial region to the third partial region being along the first direction;
a second semiconductor member of a second conductivity type, the second semiconductor member including a first semiconductor region and a second semiconductor region;
a third semiconductor member of the first conductivity type, the first semiconductor region being provided between the third partial region and the third semiconductor member in the second direction, the third semiconductor member being electrically connected to the second electrode;
a fourth semiconductor member of the second conductivity type, the second semiconductor region being provided between the second partial region and the fourth semiconductor member in the first direction, the fourth semiconductor member being electrically connected to the second electrode;
a fifth semiconductor member of the second conductivity type, at least a portion of the fifth semiconductor member being provided between the second partial region and the second electrode in the first direction, a fifth impurity concentration of the second conductivity type in the fifth semiconductor member being higher than a second impurity concentration of the second conductivity type in the second semiconductor member, and being higher than a fourth impurity concentration of the second conductivity type of the fourth semiconductor member;
a third electrode, the third partial region being provided between the first partial region and the third electrode in the first direction; and
a first insulating member including a first insulating region, the first insulating region being provided between the third partial region and at least a portion of the third electrode.

### (Technical Proposal 5)

The semiconductor device according to Technical proposal 3 or 4, wherein
a portion of the first semiconductor region is provided between the third partial region and the fifth semiconductor member in the second direction.

### (Technical Proposal 6)

The semiconductor device according to any one of Technical proposals 3-5, wherein
a portion of the fifth semiconductor member is provided between the first semiconductor region and the fourth semiconductor member in the second direction.

### (Technical Proposal 7)

The semiconductor device according to any one of Technical proposals 3-6, further comprising
a first conductive layer including silicide,
the first conductive layer being provided between the fourth semiconductor member and the second electrode and between the third semiconductor member and the second electrode, and
at least a portion of the first conductive layer being provided between a portion of the fifth semiconductor member and another portion of the fifth semiconductor member in the second direction.

### (Technical Proposal 8)

The semiconductor device according to any one of Technical proposals 1-6, further comprising
a first conductive layer including silicide,
the first conductive layer being provided between the fourth semiconductor member and the second electrode and between the third semiconductor member and the second electrode.

### (Technical Proposal 9)

The semiconductor device according to Technical proposal 7 or 8, wherein
the first conductive layer includes Ni and Si.

### (Technical Proposal 10)

The semiconductor device according to any one of Technical proposals 7-9, wherein
the first conductive layer is in contact with the second electrode.

### (Technical Proposal 11)

The semiconductor device according to Technical proposal 1 or 4, wherein
a third impurity concentration of the first conductivity type in the third semiconductor member is higher than a first impurity concentration of the first conductivity type in the first semiconductor member.

### (Technical Proposal 12)

The semiconductor device according to any one of Technical proposals 1-11, wherein
the first semiconductor member further includes a fourth partial region and a fifth partial region,
a direction from the first partial region to the fourth partial region crosses the first direction,
a direction from the fourth partial region to the fifth partial region is along the first direction, and
the fifth partial region is in Schottky contact with the second electrode.

### (Technical Proposal 13)

The semiconductor device according to Technical proposal 12, wherein
the second electrode includes a first electrode portion and a second electrode portion,
the second electrode portion is provided between the fifth partial region and the first electrode portion, and
the second electrode portion includes at least one selected from the group consisting of Ni, Ti, V, and Mo.

### (Technical Proposal 14)

The semiconductor device according to Technical proposal 12 or 13, wherein
a direction from the first partial region to the fourth partial region is along the second direction.

### (Technical Proposal 15)

The semiconductor device according to any one of Technical proposals 1-14, wherein
the third electrode extends along a third direction,
the third direction crosses a plane including the first direction and the second direction, and
the fourth semiconductor member extends along the third direction.

### (Technical Proposal 16)

The semiconductor device according to any one of Technical proposals 3-7, wherein
the third electrode extends along a third direction,
the third direction crosses a plane including the first direction and the second direction,
a plurality of the fourth semiconductor members are provided,
a direction from one of the plurality of fourth semiconductor members to another one of the plurality of fourth semiconductor members is along the third direction, and
a portion of the fifth semiconductor member is provided between the one of the plurality of fourth semiconductor members and the other one of the plurality of fourth semiconductor members.

### (Technical Proposal 17)

The semiconductor device according to any one of Technical proposals 3-7, wherein
the third electrode extends along a third direction;
the third direction crosses a plane including the first direction and the second direction,
a plurality of the fourth semiconductor members are provided,
a direction from one of the plurality of fourth semiconductor members to another one of the plurality of fourth semiconductor members is along the second direction, and
a portion of the fifth semiconductor member is provided between the one of the plurality of fourth semiconductor members and the other one of the plurality of fourth semiconductor members.

### (Technical Proposal 18)

The semiconductor device according to any one of Technical proposals 3-7, wherein
a plurality of the fourth semiconductor members are provided,
the plurality of fourth semiconductor members are arranged along the second direction and a third direction,
the third direction crosses a plane including the first direction and the second direction, and
a portion of the fifth semiconductor member is provided between the plurality of fourth semiconductor members.

### (Technical Proposal 19)

The semiconductor device according to any one of Technical proposals 1-18, wherein
the first insulating member further includes a second insulating region,
at least a portion of the second insulating region is provided between the third electrode and the second electrode.

### (Technical Proposal 20)

The semiconductor device according to any one of Technical proposals 1-19, wherein
the first semiconductor member, the second semiconductor member, the third semiconductor member, and the fourth semiconductor member include SiC.

According to the embodiment, a semiconductor device with improved characteristics can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a first semiconductor member of a first conductivity type, the first semiconductor member being provided between the first electrode and the second electrode, the first semiconductor member including a first partial region, a second partial region, and a third partial region, a second direction from the first partial region to the second partial region crossing a first direction from the first electrode to the second electrode, a direction from the first partial region to the third partial region being along the first direction;
a second semiconductor member of a second conductivity type, the second semiconductor member including a first semiconductor region and a second semiconductor region;
a third semiconductor member of the first conductivity type, the first semiconductor region being provided between the third partial region and the third semiconductor member in the second direction, the third semiconductor member being electrically connected to the second electrode;
a fourth semiconductor member, the second semiconductor region being provided between the second partial region and the fourth semiconductor member in the first direction, the fourth semiconductor member being electrically connected to the second electrode, the fourth semiconductor member being of the first conductivity type, or the fourth semiconductor member not including an impurity of the second conductivity type;
a third electrode, the third partial region being provided between the first partial region and the third electrode in the first direction; and
a first insulating member including a first insulating region, the first insulating region being provided between the third partial region and at least a portion of the third electrode.

2. The device according to claim 1, wherein
a fourth impurity concentration of the first conductivity type in the fourth semiconductor member is higher than a first impurity concentration of the first conductivity type in the first semiconductor member.

3. The device according to claim 1, further comprising:
a fifth semiconductor member of the second conductivity type,
at least a portion of the fifth semiconductor member being provided between the second partial region and the second electrode in the first direction.

4. A semiconductor device, comprising:
a first electrode;
a second electrode;
a first semiconductor member of a first conductivity type, the first semiconductor member being provided between the first electrode and the second electrode, the first semiconductor member including a first partial region, a second partial region, and a third partial region, a second direction from the first partial region to the second partial region crossing a first direction from the first electrode to the second electrode, a direction from the first partial region to the third partial region being along the first direction;
a second semiconductor member of a second conductivity type, the second semiconductor member including a first semiconductor region and a second semiconductor region;
a third semiconductor member of the first conductivity type, the first semiconductor region being provided between the third partial region and the third semiconductor member in the second direction, the third semiconductor member being electrically connected to the second electrode;
a fourth semiconductor member of the second conductivity type, the second semiconductor region being provided between the second partial region and the fourth semiconductor member in the first direction, the fourth semiconductor member being electrically connected to the second electrode;
a fifth semiconductor member of the second conductivity type, at least a portion of the fifth semiconductor member being provided between the second partial region and the second electrode in the first direction, a fifth impurity concentration of the second conductivity type in the fifth semiconductor member being higher than a second impurity concentration of the second conductivity type in the second semiconductor member, and being higher than a fourth impurity concentration of the second conductivity type of the fourth semiconductor member;
a third electrode, the third partial region being provided between the first partial region and the third electrode in the first direction; and
a first insulating member including a first insulating region, the first insulating region being provided between the third partial region and at least a portion of the third electrode.

5. The device according to claim 3, wherein
a portion of the first semiconductor region is provided between the third partial region and the fifth semiconductor member in the second direction.

6. The device according to claim 3, wherein
a portion of the fifth semiconductor member is provided between the first semiconductor region and the fourth semiconductor member in the second direction.

7. The device according to claim 3, further comprising
a first conductive layer including silicide,
the first conductive layer being provided between the fourth semiconductor member and the second electrode and between the third semiconductor member and the second electrode, and
at least a portion of the first conductive layer being provided between a portion of the fifth semiconductor member and another portion of the fifth semiconductor member in the second direction.

8. The device according to claim 1, further comprising
a first conductive layer including silicide,
the first conductive layer being provided between the fourth semiconductor member and the second electrode and between the third semiconductor member and the second electrode.

9. The device according to claim 7, wherein
the first conductive layer includes Ni and Si.

10. The device according to claim 7, wherein
the first conductive layer is in contact with the second electrode.

11. The device according to claim 1, wherein
a third impurity concentration of the first conductivity type in the third semiconductor member is higher than a first impurity concentration of the first conductivity type in the first semiconductor member.

12. The device according to claim 1, wherein
the first semiconductor member further includes a fourth partial region and a fifth partial region,
a direction from the first partial region to the fourth partial region crosses the first direction,
a direction from the fourth partial region to the fifth partial region is along the first direction, and
the fifth partial region is in Schottky contact with the second electrode.

13. The device according to claim 12, wherein
the second electrode includes a first electrode portion and a second electrode portion,
the second electrode portion is provided between the fifth partial region and the first electrode portion, and
the second electrode portion includes at least one selected from the group consisting of Ni, Ti, V, and Mo.

14. The device according to claim 12, wherein
a direction from the first partial region to the fourth partial region is along the second direction.

15. The device according to claim 1, wherein
the third electrode extends along a third direction,
the third direction crosses a plane including the first direction and the second direction, and
the fourth semiconductor member extends along the third direction.

16. The device according to claim 3, wherein
the third electrode extends along a third direction,
third direction crosses a plane including the first direction and the second direction,
a plurality of the fourth semiconductor members are provided,
a direction from one of the plurality of fourth semiconductor members to another one of the plurality of fourth semiconductor members is along the third direction, and
a portion of the fifth semiconductor member is provided between the one of the plurality of fourth semiconductor members and the other one of the plurality of fourth semiconductor members.

17. The device according to claim 3, wherein
the third electrode extends along a third direction;
the third direction crosses a plane including the first direction and the second direction,
a plurality of the fourth semiconductor members are provided,
a direction from one of the plurality of fourth semiconductor members to another one of the plurality of fourth semiconductor members is along the second direction, and
a portion of the fifth semiconductor member is provided between the one of the plurality of fourth semiconductor members and the other one of the plurality of fourth semiconductor members.

18. The device according to claim 3, wherein
a plurality of the fourth semiconductor members are provided,
the plurality of fourth semiconductor members are arranged along the second direction and a third direction,
the third direction crosses a plane including the first direction and the second direction, and
a portion of the fifth semiconductor member is provided between the plurality of fourth semiconductor members.

19. The device according to claim 1, wherein
the first insulating member further includes a second insulating region,
at least a portion of the second insulating region is provided between the third electrode and the second electrode.

20. The device according to claim 1, wherein
the first semiconductor member, the second semiconductor member, the third semiconductor member, and the fourth semiconductor member include SiC.
